(19) United States
(12) Patent Application Publication
(10) Pub. No.: US 2026/0305265 A1
(43) Pub. Date: Oct. 1, 2026

(54) SACRIFICIAL TEST STRUCTURES FOR ADVANCED PACKAGING

(71) Applicant: International Business Machines Corporation, Armonk, NY (US)

(72) Inventors: Uzma Rana, Slingerlands, NY (US); Reinaldo Vega, Mahopac, NY (US); Takashi Ando, Eastchester, NY (US); David Wolpert, Poughkeepsie, NY (US)

(21) Appl. No.: 19/094,865

(22) Filed: Mar. 29, 2025

(51) Int. Cl. H01L 21/66; H01L 23/48; H01L 23/544

(52) U.S. Cl. CPC H10P 74/273; H10W 20/20; H10W 46/00; H10W 46/301

(57) ABSTRACT

Sacrificial test structures for testing with advanced packaging are provided. In one aspect, a device includes: a product structure having vias; and an etch-stop layer disposed on the product structure in between the vias, such that a surface of the etch-stop layer is coplanar with surfaces of the vias. A sacrificial test structure can be employed over the product structure, with the etch-stop layer therebetween. A method for using the present product structures is also provided.

### BACKGROUND

The present invention relates generally to the electrical, electronic and computer arts and, more particularly, to sacrificial test structures used for testing with advanced packaging.

Advanced packaging refers to the integration of multiple components such as integrated circuits into a single electronic device. An example of an advanced packaging technique includes a three-dimensional (or 3D) integrated circuit architecture that involves stacked integrated circuits. Another example is the so-called 2.5D architecture where multiple integrated circuits are combined without stacking, such as by placing them side-by-side on a substrate.

However, due to their increased complexity, chip yield verification in such 2.5D and 3D integrated products is not straightforward. Namely, an effective testing method for 2.5D and 3D integrated products is not available, because test probes inevitably induce metal damage on top of the tested surface. As such, the post-probe products with top metal damage cannot be feasibly packaged.

### BRIEF SUMMARY

Principles of the invention provide sacrificial test structures used for testing with advanced packaging. In one aspect, a device is provided. The device includes: a product structure having vias; and an etch-stop layer disposed on the product structure in between the vias, such that a surface of the etch-stop layer is coplanar with surfaces of the vias.

In another aspect, another device is provided. The device includes: a product structure having vias with recesses therein; and alignment mark shadows on at least one surface of the product structure outward from the vias. The product structure includes, e.g., a chip or a wafer.

In yet another aspect, a method is provided. The method includes: forming an etch-stop layer on a product structure, where the product structure has first vias, and where a top surface of the etch-stop layer is coplanar with top surfaces of the first vias; forming a sacrificial test structure over the etch-stop layer, where the sacrificial test structure has second vias in direct contact with the first vias; testing the product structure through the sacrificial test structure using the second vias; and removing the sacrificial test structure along with any damage to it caused by the testing.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Devices with sacrificial test structures which enable bumpless 2.5D and 3D integration with test/yield verification;
Whereby these sacrificial test structures enable pre-packaged test/yield verification, i.e., testing before integration into package (2.5D/3D);
Whereby the present pre-packaged testing ahead of integration will lead to less loss of product;
Whereby these sacrificial test structures can be employed on a front of a pre-packaged product (e.g., a chip, wafer, etc.), a back of the product, or both;
Whereby the present devices with sacrificial test structures are scalable to the technology; and
Whereby a clean post-testing interface is provided for integration into package (2.5D/3D).

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-D are diagrams illustrating an exemplary device employing a test-ready product structure, all of which are cross-sectional views except for FIG. 1C which is a top-down view, according to aspects of the invention;

FIGS. 2A-D are diagrams illustrating another exemplary device employing a test-ready product structure, all of which are cross-sectional views except for FIG. 2C which is a bottom-up view, according to aspects of the invention;

FIGS. 3A-E are diagrams illustrating yet another exemplary device employing a test-ready product structure, all of which are cross-sectional views except for FIG. 3C which is a top-down view and FIG. 3D which is a bottom-up view, according to aspects of the invention;

FIGS. 4A and 4B are diagrams illustrating exemplary methodologies for using the present test-ready product structure, according to aspects of the invention; and

FIG. 5 is a diagram illustrating a wafer-level test-ready product structure, according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As provided above, chip yield verification in 2.5D and 3D integrated products presents a notable challenge which is further compounded when coupled with bumpless interconnect technology. For instance, the use of test probes on bumpless chips inevitably induces some metal damage on the chip surface. Such post-probe chips with top metal damage cannot be feasibly packaged.

The term “bumpless,” as used herein, generally refers to any bonding method where components such as wafers, chips, chiplets, etc. are joined without the use of traditional solder bumps. Bumpless bonding often relies on direct metal-to-metal (e.g., copper-to-copper) contact between the respective components. By way of example only, hybrid bonding is one type of bumpless bonding technique which involves a ‘hybrid’ bonding interface with both direct metal-to-metal and dielectric-to-dielectric bonds.

With reduced pitch and lower impedance, bumpless technology advantageously enhances scalability. For instance, bumpless bonding enables the expansion of chiplet integration into a package design. “Chiplet” is used herein in its ordinary sense to refer to a small, modular chip that performs a specific function such as a processor core, a memory block, an I/O driver, a signal processing unit, or the like; e.g., a type of chip (or die) specialized for a specific function.

Advantageously, provided herein are test-ready 2.5D and 3D integrated circuit designs with bumpless interconnect technology which enable easy and effective pre-packaged test/yield verification through the use of sacrificial metal layers. These sacrificial metal layers can be employed on a front of the product (e.g., chip, wafer, etc.), a back of the product, or both.

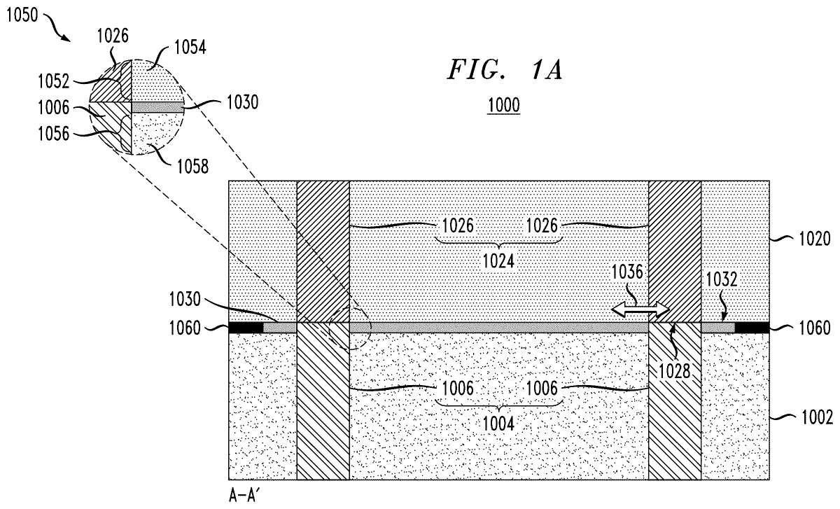

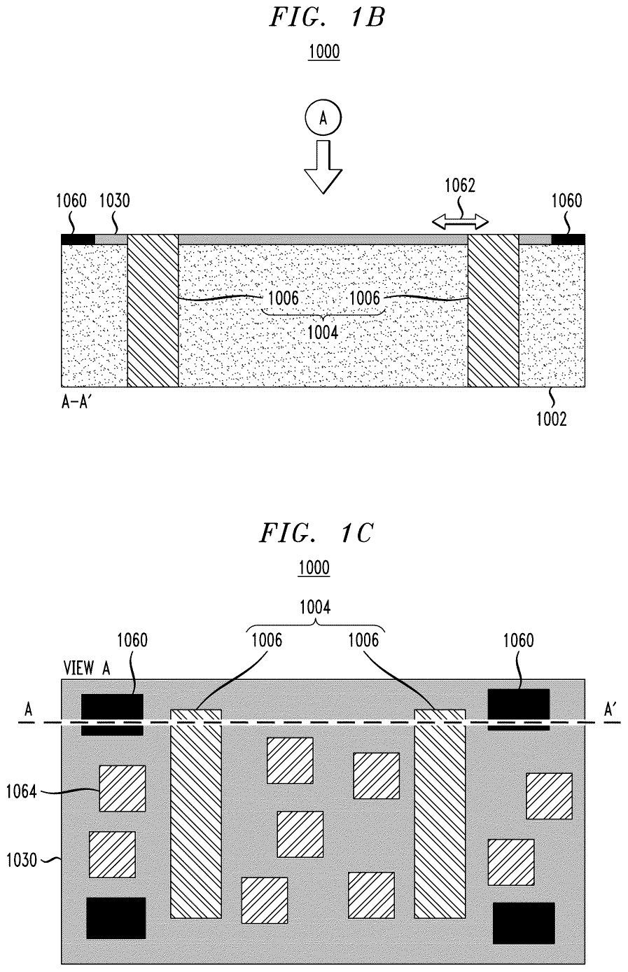

For instance, referring first to FIG. 1A (a cross-sectional view), a device 1000 having a test-ready product structure 1002 is shown having a (first) population 1004 of (first) vias 1006. In the example provided in FIG. 1A, the product structure 1002 shown is a product chip. However, embodiments are contemplated herein where the present techniques are applied at a wafer-level scale. Further, by “test-ready” it is meant that the product structure 1002 (product chip, product wafer, etc.) is ready for pre-package testing.

Namely, disposed on a frontside of the product structure 1002 is a sacrificial test structure 1020 having a (second) population 1024 of (second) vias 1026 in direct contact with the vias 1006. The term “sacrificial,” as used herein, generally refers to any material or structure that is used in one part of a process and then later removed, in whole or in part. For instance, as will be described in detail below, the sacrificial test structure 1020 will be used for pre-package testing of the product structure 1002, and then removed before packaging of the product structure 1002. While not explicitly shown in the figures, it would be understood by one skilled in the art that the product structure 1002 can have pre-built structures such as transistors, diodes, capacitors, resistors, interconnects, wiring, etc. for specific memory, radio-frequency, logic, etc. applications. In a non-limiting example, it should be noted that in some cases, the distance between the two vias 1006 could be a large fraction of the width of the chip (e.g., more than 50%) and/or could be sufficient such that there are many transistors, diodes, capacitors, and/or resistors, therebetween; e.g., tens, hundreds, thousands, and more of transistors, diodes, capacitors, and/or resistors.

According to an exemplary embodiment, the vias 1006 and 1026 are each formed from a contact metal. By way of example only, suitable contact metals include, but are not limited to, copper (Cu), tungsten (W), nickel (Ni), platinum (Pt), cobalt (Co), ruthenium (Ru), titanium (Ti), tantalum (Ta), aluminum (Al) and/or any combination thereof. In some embodiments, including that shown in FIG. 1A, the vias 1006 extend fully through the product structure 1002 and the vias 1026 extend fully through the sacrificial test structure 1020. However, this is not a requirement, and embodiments are contemplated herein where one or more of the vias 1006 extend only part-way through the product structure 1002 and/or one or more of the vias 1026 extend only part-way through the sacrificial test structure 1020, as long as the vias 1006 and 1026 are in direct contact with one another. Namely, according to an exemplary embodiment, the sacrificial test structure 1020 is built on top of the product structure 1002 such that, as shown in FIG. 1A, there is direct metal-to-metal contact between the vias 1006 of the product structure 1002 and the vias 1026 of the sacrificial test structure 1020.

Alignment marks 1060 can be etched on the surface of the product structure 1002 outward of the vias 1006. Post testing, these alignment marks 1060 will help ensure proper positioning of the product structure 1002 with other corresponding structures during packaging that, as described in detail below, can involve bumpless bonding.

As further shown in FIG. 1A, an etch-stop layer 1030 is disposed on the product structure 1002 between the vias 1006, such that the etch-stop layer 1030 is present between the product structure 1002 and the sacrificial test structure 1020. By way of example only, etch-stop layer 1030 can have a thickness of from about 2 nanometers (nm) to about 50 nm. In an exemplary, non-limiting embodiment, the etch-stop layer 1030 is positioned such that a top surface 1032 of the etch-stop layer 1030 is coplanar with an interface 1028 between the vias 1006 of the product structure 1002 and the vias 1026 of the sacrificial test structure 1020 (see arrow 1036).

As will be described in detail below, the etch-stop layer 1030 will aid in removal of the sacrificial test structure 1020 post testing/pre-packaging of the product structure 1002. To do so, the etch-stop layer 1030 is formed from a different material than the sacrificial test structure 1020 at the interface 1028 to provide etch selectivity. For instance, according to an exemplary embodiment, in at least a region 1052 abutting the etch-stop layer 1030, the vias 1026 of the sacrificial test structure 1020 are surrounded by a (first) interlayer dielectric 1054. Similarly, in at least a region 1056 abutting the etch-stop layer 1030, the vias 1006 of the product structure 1002 are surrounded by a (second) interlayer dielectric 1058. See magnified view 1050. Suitable interlayer dielectric materials include, but are not limited to, silicon oxycarbide (SiOC) and/or oxide low-κ materials such as silicon oxide (SiOₓ) and/or oxide ultralow-κ interlayer dielectric (ULK-ILD) materials such as porous organosilicate glass (pSiCOH).

By comparison, the etch-stop layer 1030 is formed from a different material, one having etch-selectivity to the first/second interlayer dielectrics 1054/1058. For instance, by way of example only, when the first/second interlayer dielectrics 1054/1058 are formed from an oxide material (see above), the etch-stop layer 1030 can be formed from a nitride material, such as silicon nitride (SiN).

That way, following testing, the sacrificial test structure 1020 can easily be removed selective to the product structure 1002 using an etching process (or combination of etching processes), stopping on the etch-stop layer 1030. See, for example, FIG. 1B. Suitable etching processes include, but are not limited to, dry etching processes such as reactive ion etching (RIE), wet chemical etching, and/or chemical-mechanical polishing (CMP).

Namely, FIG. 1B (a cross-sectional view) depicts the product structure 1002 after the sacrificial test structure 1020 has been removed. Depending on the selectivity of the etching process employed, at least a portion of the etch-stop layer 1030 can remain on the frontside of the product structure 1002, as can the alignment marks 1060. In the exemplary embodiment depicted in FIG. 1B, the etch-stop layer 1030 remains present in between and alongside the vias 1006 with a top surface of the etch-stop layer 1030 being coplanar with the (now-exposed) top surfaces of the vias 1006. See arrow 1062. The alignment marks 1060 remain present on the product structure 1002 outward from the vias 1006.

As highlighted above, the sacrificial test structure 1020 is removed from the (pre-package) product structure 1002 after testing/yield verification. Advantageously, any metal damage incurred during this testing/yield verification process will be to the sacrificial test structure 1020, not the product structure 1002. Accordingly, any such metal damage will then be simply removed along with the sacrificial test structure 1020, and thus will have no impact on the packaged product.

FIG. 1C provides an exemplary top-down view (from viewpoint A) of the product structure 1002 after the sacrificial test structure 1020 has been removed. The cross-sectional views in FIGS. 1A, 1B and 1D are taken along line A-A′ as shown in FIG. 1C. As shown in FIG. 1C, in this example, the etch-stop layer 1030 remains present over the (underlying) product structure 1002. However, as provided above, the top surface of the etch-stop layer 1030 is coplanar with the top surfaces of the vias 1006. Thus, vias 1006 are visible from the top-down, as are metal interconnects 1064 (e.g., metal lines, vias, etc.) and the alignment marks 1060.

Alternatively, even in a case where the etch-stop layer 1030 is completely removed by an aggressive etch, use of the sacrificial test structure 1020 is still evident. See FIG. 1D (a cross-sectional view). Namely, as shown in FIG. 1D, over-etch of the sacrificial test structure 1020 through the etch-stop layer 1030 can result in recesses 1066 being formed in the tops of the vias 1006. Further, shadows 1090 of the alignment marks 1060 (also referred to herein as “alignment mark shadows”) may be evident on a top surface of the product structure 1002 outward from the vias 1006. Namely, these alignment mark shadows are what remains of the respective alignment mark etchings into the product structure following complete removal of the overlying sacrificial test structure and etch-stop layer.

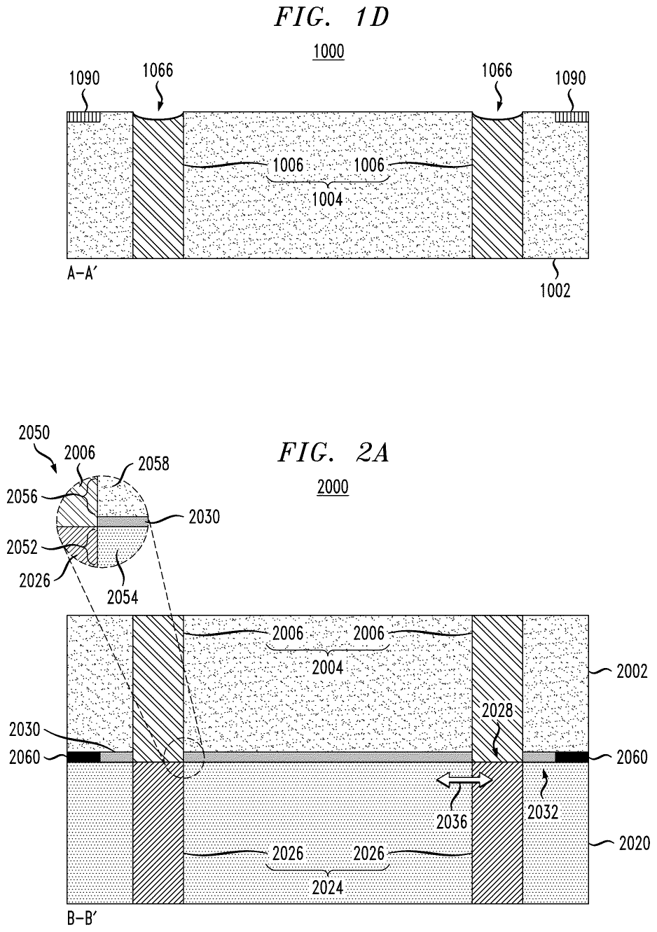

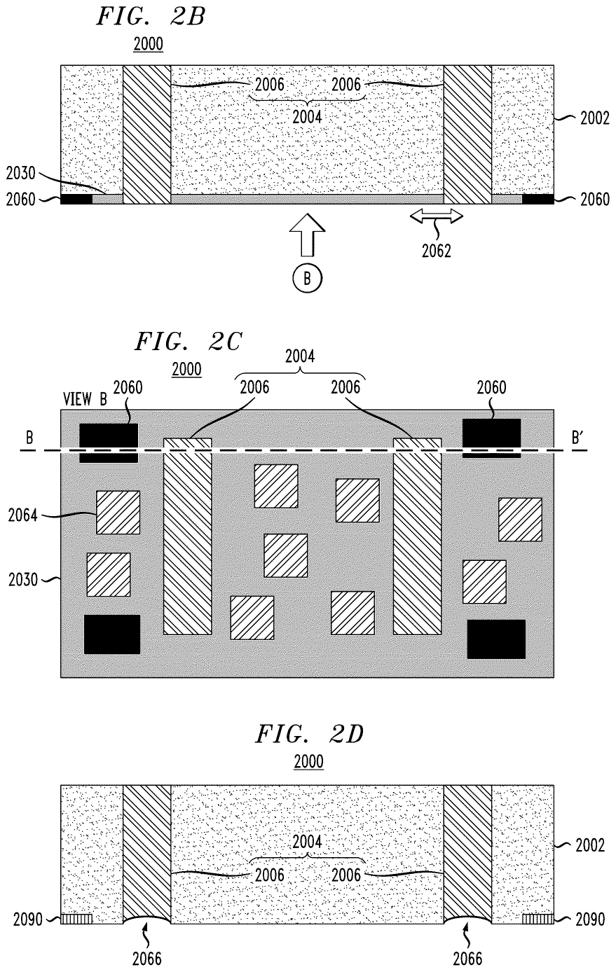

Embodiments are also contemplated herein where the present sacrificial test structure is instead located on a backside of the product structure. See, for example, FIGS. 2A-D. For instance, referring first to FIG. 2A (a cross-sectional view), a device 2000 is shown having a test-ready product structure 2002 with a (first) population 2004 of (first) vias 2006, and a sacrificial test structure 2020 having a (second) population 2024 of (second) vias 2026 disposed on a backside of the product structure 2002. In the example provided in FIG. 2A, the product structure 2002 shown is a product chip. However, as highlighted above, embodiments are contemplated herein where the present techniques are applied at a wafer-level scale. Further, by “test-ready” it is meant that the product structure 2002 (product chip, product wafer, etc.) is ready for pre-package testing. While not explicitly shown in the figures, it would be understood by one skilled in the art that the product structure 2002 can have pre-built structures such as transistors, diodes, capacitors, resistors, interconnects, wiring, etc. for specific memory, radio-frequency, logic, etc. applications.

According to an exemplary embodiment, the vias 2006 and 2026 are each formed from a contact metal (e.g., Cu, W, Ni, Pt, Co, Ru, Ti, Ta and/or Al). In some embodiments, including that shown in FIG. 2A, the vias 2006 extend fully through the product structure 2002 and the vias 2026 extend fully through the sacrificial test structure 2020. However, this is not a requirement, and embodiments are contemplated herein where one or more of the vias 2006 extend only part-way through the product structure 2002 and/or one or more of the vias 2026 extend only part-way through the sacrificial test structure 2020, as long as the vias 2006 and 2026 are in direct contact with one another.

According to an exemplary embodiment, the sacrificial test structure 2020 is built on the bottom of the product structure 2002 such that, as shown in FIG. 2A, there is direct metal-to-metal contact between the vias 2006 of the product structure 2002 and the vias 2026 of the sacrificial test structure 2020. In the same manner as above, alignment marks 2060 can be etched on the surface of the product structure 2002 outward of the vias 2006. Post testing, these alignment marks 2060 will help ensure proper positioning of the product structure 2002 with other corresponding structures during packaging that, as described in detail below, can involve bumpless bonding.

An etch-stop layer 2030 is disposed on the product structure 2002 between the vias 2006, such that the etch-stop layer 2030 is present between the product structure 2002 and the sacrificial test structure 2020. By way of example only, etch-stop layer 2030 can have a thickness of from about 2 nm to about 50 nm. In an exemplary, non-limiting embodiment, the etch-stop layer 2030 is positioned such that a bottom surface 2032 of the etch-stop layer 2030 is coplanar with an interface 2028 between the vias 2006 of the product structure 2002 and the vias 2026 of the sacrificial test structure 2020 (see arrow 2036).

The etch-stop layer 2030 will aid in removal of sacrificial test structure 2020 post testing/pre-packaging of the product structure 2002. To do so, the etch-stop layer 2030 is formed from a different material than the sacrificial test structure 2020 at the bonding interface 2028 to provide an etch selectivity. For instance, according to an exemplary embodiment, in at least a region 2052 abutting the etch-stop layer 2030, the vias 2026 of the sacrificial test structure 2020 are surrounded by a (first) interlayer dielectric 2054. Similarly, in at least a region 2056 abutting the etch-stop layer 2030, the vias 2006 of the product structure 2002 are surrounded by a (second) interlayer dielectric 2058. See magnified view 2050. Suitable interlayer dielectric materials include, but are not limited to, SiOC and/or oxide low-κ materials such as SiOₓ and/or oxide ULK-ILD materials such as pSiCOH.

By comparison, the etch-stop layer 2030 is formed from a different material, one having etch-selectivity to the first/second interlayer dielectrics 2054/2058. For instance, by way of example only, when the first/second interlayer dielectrics 2054/2058 are formed from an oxide material (see above), the etch-stop layer 2030 can be formed from a nitride material, such as SiN.

That way, following testing, the sacrificial test structure 2020 can easily be removed selective to the product structure 2002 using an etching process (or combination of etching processes), stopping on the etch-stop layer 2030. See, for example, FIG. 2B. Suitable etching processes include, but are not limited to, dry etching processes such as RIE, wet chemical etching, and/or CMP.

Namely, FIG. 2B (a cross-sectional view) depicts the product structure 2002 after the sacrificial test structure 2020 has been removed. Depending on the selectivity of the etching process employed, at least a portion of the etch-stop layer 2030 can remain on the backside of the product structure 2002, as can the alignment marks 2060. In the exemplary embodiment depicted in FIG. 2B, the etch-stop layer 2030 remains present in between and alongside the vias 2006 with a bottom surface of the etch-stop layer 2030 being coplanar with the (now-exposed) bottom surfaces of the vias 2006. See arrow 2062. The alignment marks 2060 remain present on the product structure 2002 outward from the vias 2006.

As highlighted above, the sacrificial test structure 2020 is removed from the (pre-package) product structure 2002 after testing/yield verification. Advantageously, any metal damage incurred during this testing/yield verification process will be to the sacrificial test structure 2020, not the product structure 2002. Accordingly, any such metal damage will then be simply removed along with the sacrificial test structure 2020, and thus will have no impact on the packaged product.

FIG. 2C provides an exemplary bottom-up view (from viewpoint B) of the product structure 2002 after the sacrificial test structure 2020 has been removed. The cross-sectional views in FIGS. 2A, 2B and 2D are taken along line B-B′ as shown in FIG. 2C. As shown in FIG. 2C, in this example, the etch-stop layer 2030 remains present under the product structure 2002. However, as provided above, the bottom surface of the etch-stop layer 2030 is coplanar with the bottom surfaces of the vias 2006. Thus, vias 2006 are visible from the bottom-up, as are metal interconnects 2064 (e.g., metal lines, vias, etc.) and the alignment marks 2060.

Alternatively, even in a case where the etch-stop layer 2030 is completely removed by an aggressive etch, use of the sacrificial test structure 2020 is still evident. See FIG. 2D (a cross-sectional view). Namely, as shown in FIG. 2D, over-etch of the sacrificial test structure 2020 through the etch-stop layer 2030 can result in recesses 2066 being formed in the bottoms of the vias 2006. Further, shadows 2090 of the alignment marks 2060 (also referred to herein as “alignment mark shadows”) may be evident on a bottom surface of the product structure 2002 outward from the vias 2006.

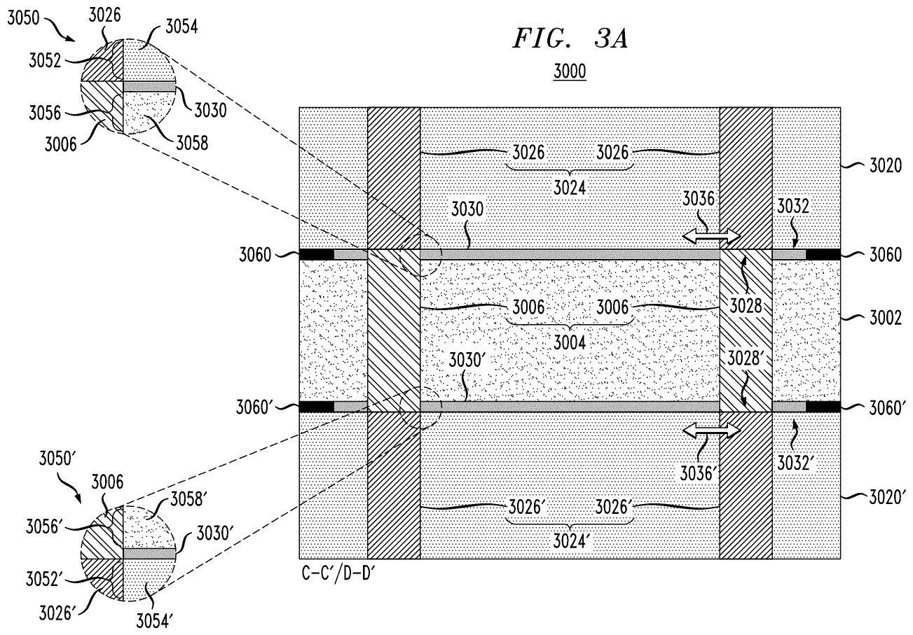

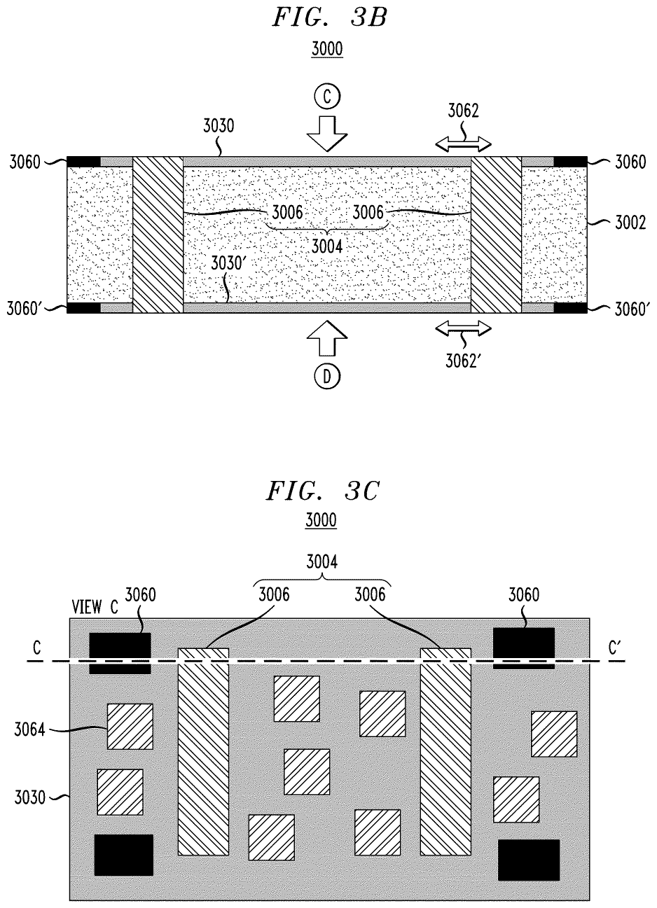

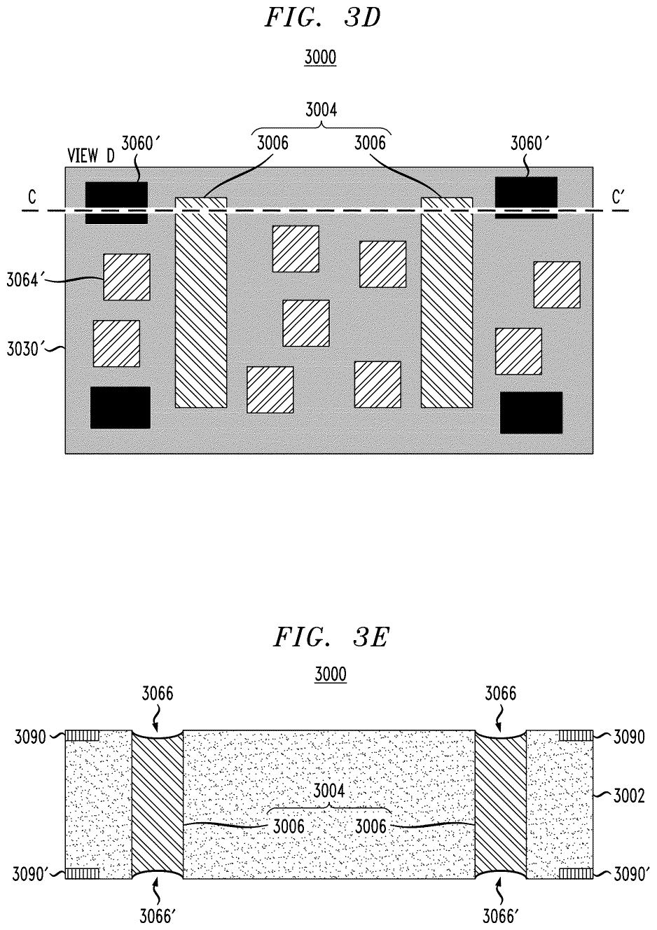

A combination of the above configurations may also be employed where, for example, the present sacrificial test structures are employed on both a frontside and a backside of the product structure. See, for example, FIGS. 3A-E. For instance, referring first to FIG. 3A (a cross-sectional view), a device 3000 is shown having a test-ready product structure 3002 with a (first) population 3004 of (first) vias 3006, a (front) sacrificial test structure 3020 having a (second) population 3024 of (second) vias 3026 disposed on a frontside of the product structure 3002, and a (back) sacrificial test structure 3020′ having a (third) population 3024′ of (third) vias 3026′ disposed on a backside of the product structure 3002. In the example provided in FIG. 3A, the product structure 3002 shown is a product chip. However, as highlighted above, embodiments are contemplated herein where the present techniques are applied at a wafer-level scale. Further, by “test-ready” it is meant that the product structure 3002 (product chip, product wafer, etc.) is ready for pre-package testing. While not explicitly shown in the figures, it would be understood by one skilled in the art that the product structure 3002 can have pre-built structures such as transistors, diodes, capacitors, resistors, interconnects, wiring, etc. for specific memory, radio-frequency, logic, etc. applications.

According to an exemplary embodiment, the vias 3006, 3026 and 3026′ are each formed from a contact metal (e.g., Cu, W, Ni, Pt, Co, Ru, Ti, Ta and/or Al). In some embodiments, including that shown in FIG. 3A, the vias 3006 extend fully through the product structure 3002 and the vias 3026/3026′ extend fully through the sacrificial test structures 3020/3020′. However, this is not a requirement, and embodiments are contemplated herein where one or more of the vias 3006 extend only part-way through the product structure 3002 and/or one or more of the vias 3026/3026′ extend only part-way through the sacrificial test structures 3020/3020′, as long as the vias 3026/3026′ are in direct contact with the vias 3006.

According to an exemplary embodiment, the sacrificial test structures 3020/3020′ are built on the top and bottom respectively of the product structure 3002 such that, as shown in FIG. 3A, there is direct metal-to-metal contact between a frontside of the vias 3006 of the product structure 3002 and the vias 3026 of the sacrificial test structure 3020, and direct metal-to-metal contact between a backside of the vias 3006 of the product structure 3002 and the vias 3026′ of the sacrificial test structure 3020′. In the same manner as above, alignment marks 3060/3060′ can be etched on the surfaces of the product structure 3002 outward from the vias 3026/3026′. Post testing, these alignment marks 3060/3060′ will help ensure proper positioning of the product structure 3002 with other corresponding structures during packaging that, as described in detail below, can involve bumpless bonding.

A (first) etch-stop layer 3030 is disposed on the frontside of the product structure 3002 between the vias 3006, and a (second) etch-stop layer 3030′ is disposed on the backside of the product structure 3002 between the vias 3006. By way of example only, the etch-stop layers 3030 and 3030′ can each have a thickness of from about 2 nm to about 50 nm. In an exemplary, non-limiting embodiment, the etch-stop layer 3030 is positioned such that a top surface 3032 of the etch-stop layer 3030 is coplanar with an interface 3028 between the vias 3006 of the product structure 3002 and the vias 3026 of the sacrificial test structure 3020 (see arrow 3036). Similarly, the etch-stop layer 3030′ is positioned such that a bottom surface 3032′ of the etch-stop layer 3030′ is coplanar with an interface 3028′ between the vias 3006 of the product structure 3002 and the vias 3026′ of the sacrificial test structure 3020′ (see arrow 3036′).

The etch-stop layers 3030 and 3030′ will aid in removal of the sacrificial test structures 3020 and 3020′ post testing/pre-packaging of the product structure 3002. To do so, the etch-stop layers 3030 and 3030′ are formed from a different material than the sacrificial test structure 3020 at the interfaces 3028 and 3028′ to provide etch selectivity. For instance, according to an exemplary embodiment, in at least a region 3052 abutting the etch-stop layer 3030, the vias 3026 of the sacrificial test structure 3020 are surrounded by a (first) interlayer dielectric 3054. Similarly, in at least a region 3056 abutting the etch-stop layer 3030, the vias 3006 of the product structure 3002 are surrounded by a (second) interlayer dielectric 3058. See magnified view 3050. In the same manner, in at least a region 3052′ abutting the etch-stop layer 3030′, the vias 3026′ of the sacrificial test structure 3020′ are surrounded by a (third) interlayer dielectric 3054′. Similarly, in at least a region 3056′ abutting the etch-stop layer 3030′, the vias 3006 of the product structure 3002 are surrounded by a (fourth) interlayer dielectric 3058′. See magnified view 3050′. Suitable interlayer dielectric materials include, but are not limited to, SiOC and/or oxide low-κ materials such as SiOₓ and/or oxide ULK-ILD materials such as pSiCOH.

By comparison, the etch-stop layers 3030 and 3030′ are formed from a different material, one having etch-selectivity to the first/second/third/fourth interlayer dielectrics 3054/3058/3054′/3058′. For instance, by way of example only, when the first/second/third/fourth interlayer dielectrics 3054/3058/3054′/3058′ are formed from an oxide material (see above), the etch-stop layers 3030 and 3030′ can each be formed from a nitride material, such as SiN.

That way, following testing, the sacrificial test structures 3020 and 3020′ can easily be removed selective to the product structure 3002 using an etching process (or combination of etching processes), stopping on the etch-stop layers 3030 and 3030′, respectively. See, for example, FIG. 3B. Suitable etching processes include, but are not limited to, dry etching processes such as RIE, wet chemical etching, and/or CMP.

Namely, FIG. 3B (a cross-sectional view) depicts the product structure 3002 after the sacrificial test structures 3020 and 3020′ have been removed. Depending on the selectivity of the etching process employed, at least a portion of the etch-stop layers 3030 and 3030′ can remain on the frontside and backside of the product structure 3002, respectively, as can the alignment marks 3060 and 3060′. In the exemplary embodiment depicted in FIG. 3B, the etch-stop layer 3030 remains present in between and alongside the vias 3006 with a top surface of the etch-stop layer 3030 being coplanar with the (now-exposed) top surfaces of the vias 3006. See arrow 3062. Similarly, the etch-stop layer 3030′ remains present in between and alongside the vias 3006 with a bottom surface of the etch-stop layer 3030′ being coplanar with the (now-exposed) bottom surfaces of the vias 3006. See arrow 3062′. The alignment marks 3060 and 3060′ remain present on the product structure 3002 outward from the vias 3006.

As highlighted above, the sacrificial test structures 3020 and 3020′ are removed from the (pre-package) product structure 3002 after testing/yield verification. Advantageously, any metal damage incurred during this testing/yield verification process will be to sacrificial test structures 3020 and 3020′, not the product structure 3002. Accordingly, any such metal damage will then be simply removed along with the sacrificial test structures 3020 and 3020′, and thus will have no impact on the packaged product.

FIG. 3C provides an exemplary top-down view (from viewpoint C) of the product structure 3002 after the sacrificial test structure 3020 has been removed. The cross-sectional views in FIGS. 3A, 3B and 3E are taken along line C-C′ as shown in FIG. 3C and FIG. 3D. As shown in FIG. 3C, in this example, the etch-stop layer 3030 remains present over the product structure 3002. However, as provided above, the top surface of the etch-stop layer 3030 is coplanar with the top surfaces of the vias 3006. Thus, the vias 3006 are visible from the top-down, as are metal interconnects 3064 (e.g., metal lines, vias, etc.) and the alignment marks 3060.

FIG. 3D provides an exemplary bottom-up view (from viewpoint D) of the product structure 3002 after the sacrificial test structure 3020′ has been removed. As shown in FIG. 3D, in this example, the etch-stop layer 3030′ remains present under the product structure 3002. However, as provided above, the bottom surface of the etch-stop layer 3030′ is coplanar with the bottom surfaces of the vias 3006. Thus, the vias 3006 are visible from the bottom-up, as are metal interconnects 3064′ (e.g., metal lines, vias, etc.) and the alignment marks 3060′.

Alternatively, even in a case where the etch-stop layers 3030 and 3030′ are completely removed by an aggressive etch, use of the sacrificial test structures 3020 and 3020′ is still evident. See FIG. 3E (a cross-sectional view). Namely, as shown in FIG. 3E, over-etch of the sacrificial test structures 3020 and 3020′ through the etch-stop layers 3030 and 3030′, respectively, can result in recesses 3066 and 3066′ being formed in the tops and bottoms of the vias 3006. Further, shadows 3090 and 3090′ (see above) of the alignment marks 3060 and 3060′ (also referred to herein as “alignment mark shadows”) may be evident on top and bottom surfaces of the product structure 3002, respectively, outward from the vias 3006.

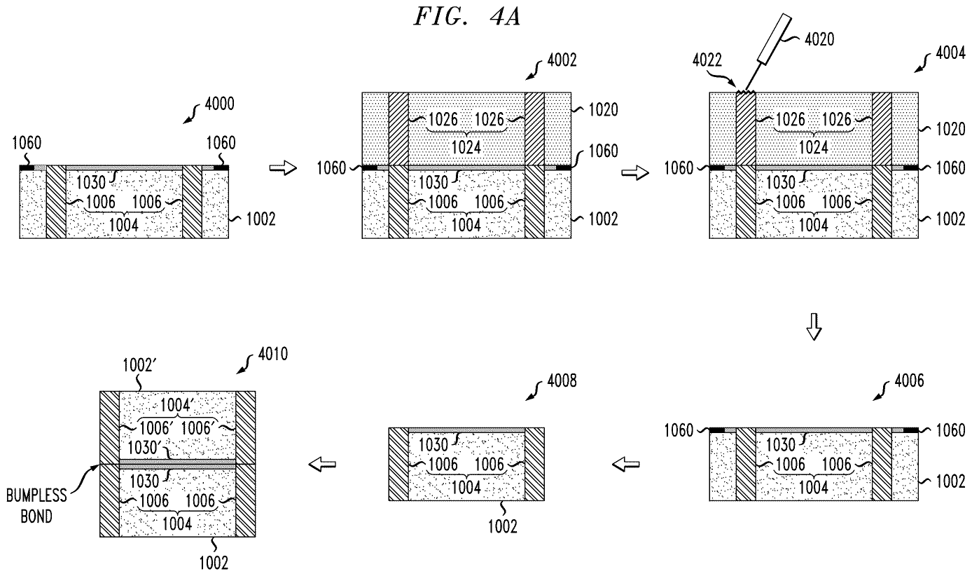

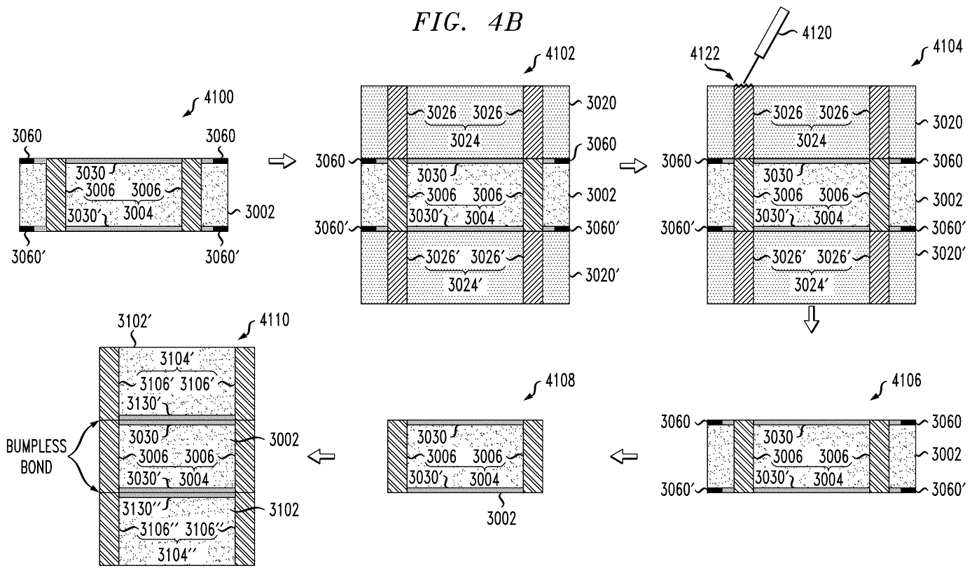

An exemplary methodology for using the present test-ready product structures is now described by way of reference to FIG. 4A. While the example in FIG. 4A depicts use of the product structure 1002 (from FIGS. 1A-D, above), it is to be understood that any of the test-ready product structures presented herein may be employed in the same manner described. Further, it is noted that like structures are numbered alike in the figures.

Referring to FIG. 4A, the process begins with the product structure 1002 (e.g., a chip, a wafer, etc.) having the (first) population 1004 of (first) vias 1006 and, in step 4000, the etch-stop layer 1030 is formed on the product structure 1002. By way of example only, a process such as chemical vapor deposition (CVD), atomic layer deposition (ALD) or physical vapor deposition (PVD) can be employed to deposit a suitable etch-stop material (see above) onto the product structure 1002. Following deposition, a process such as CMP can be used to polish the etch-stop material stopping on and exposing the vias 1006. As described above, the alignment marks 1060 can be present on the surface of the product structure 1002 outward from the vias 1006.

In step 4002, the sacrificial test structure 1020 is formed on the product structure 1002 over the etch-stop layer 1030 and alignment marks 1060. By way of example only, standard metallization techniques can be employed to form the sacrificial test structure 1020 on the product structure 1002. As described in detail above, the sacrificial test structure 1020 has the (second) population 1024 of (second) vias 1026, each of which can be formed from a contact metal(s) thereby enabling direct metal-to-metal contact between the vias 1006 and the vias 1026.

As highlighted above, the etch-stop layer 1030 is formed from a different material than the sacrificial test structure 1020 at the interface 1028 (see FIG. 1A, above) between the vias 1006 and the vias 1026 to provide etch selectivity. Further, another unique feature of the present configuration is that the top surface 1032 (see FIG. 1A, above) of the etch-stop layer 1030 is coplanar with the interface 1028.

The sacrificial test structure 1020 shown is disposed on a frontside of the product structure 1002. However, as described in detail above, some variations contemplated herein include having a sacrificial test structure 2020 with vias 2026 disposed on a backside of a product structure 2002 with an etch-stop layer 2030 therebetween and alignment marks 2060 (as depicted, e.g., in FIG. 2A above) or a front sacrificial test structure 3020 with vias 3026 disposed on a frontside of a product structure 3002 with an etch-stop layer 3030 therebetween and alignment marks 3060 in combination with a back sacrificial test structure 3020′ with vias 3026′ disposed on a backside of the product structure 3002 with an etch-stop layer 3030′ therebetween and alignment marks 3060′ (as depicted, e.g., in FIG. 3A above).

In step 4004, the product structure 1002 is tested through the sacrificial test structure 1020 using the vias 1026 (or vias 2026, vias 3026/3026′, etc. in the above variants). For instance, as shown in FIG. 4A, a test probe 4020 can be used to gain access to the product structure 1002 by way of the vias 1026 (which directly contact the vias 1006), rather than directly probing the vias 1006 of the product structure 1002. Doing so, advantageously limits any metal damage 4022 from the testing performed in step 4004 to the sacrificial test structure 1020 which, as its name implies, will be removed later on in the process.

Namely, in step 4006, the sacrificial test structure 1020 (or sacrificial test structure 2020, front sacrificial test structure 3020/back sacrificial test structure 3020′, etc. in the above variants) is removed along with any metal damage 4022 to it caused by the testing. As described in detail above, an etching process (or combination of etching processes) can be employed in step 4006, stopping on the etch-stop layer 1030 (or etch-stop layer 2030, etch-stop layer 3030/etch-stop layer 3030′, etc. in the above variants). Suitable etching processes include, but are not limited to, dry etching processes such as RIE, wet chemical etching, and/or CMP. As above, embodiments are contemplated herein where at least a portion of the etch-stop layer 1030 (or etch-stop layer 2030, etch-stop layer 3030/etch-stop layer 3030′, etc. in the above variants) remains following the removal etch.

However, even in a case where the etch-stop layer 1030 (or etch-stop layer 2030, etch-stop layer 3030/etch-stop layer 3030′, etc. in the above variants) is completely removed, use of the sacrificial test structure 1020 (or sacrificial test structure 2020, front sacrificial test structure 3020/back sacrificial test structure 3020′, etc. in the above variants) is still evident by recesses 1066 (or recesses 2066, recesses 3066/recesses 3066′, etc. in the above variants as depicted, e.g., in FIG. 2D, FIG. 3E, etc.) and shadows 1090 (or shadows 2090, shadows 3090/shadows 3090′, etc. in the above variants) of the alignment marks 1060 (or alignment marks 2060, alignment marks 3060/alignment marks 3060′, etc. in the above variants).

The now-tested product structure 1002 can then be packaged. However, any further processing that is needed prior to packaging may be performed. For instance, by way of example only, as shown in step 4008, scribing can be used to obtain the desired final product structure 1002 for packaging. Advantageously, any damage resulting from the above-described testing is removed along with the sacrificial test structure 1020 (or sacrificial test structure 2020, front sacrificial test structure 3020/back sacrificial test structure 3020′, etc. in the above variants). What remains is a clean post-testing interface for packaging, which is especially important for integration techniques such as bumpless bonding. For example, as shown in step 4010 the final product structure 1002 can be joined with a complementary product structure 1002′, e.g., by way of bumpless bonding between vias 1006 and 1006′. In this non-limiting example, the product structure 1002′ is also produced and pre-package tested using the present techniques. As such, the product structure 1002′ includes a population 1004′ of vias 1006′, an etch-stop layer 1030′, etc.

For completeness, the process involving both frontside and backside sacrificial test structures is illustrated in FIG. 4B. While the example in FIG. 4B depicts use of the product structure 3002 (from FIGS. 3A-E, above), it is to be understood that any of the test-ready product structures presented herein may be employed in the same manner described. Further, it is noted that like structures are numbered alike in the figures.

Referring to FIG. 4B, the process begins with the product structure 3002 (e.g., a chip, a wafer, etc.) having the (first) population 3004 of (first) vias 3006 and, in step 4100, the etch-stop layers 3030 and 3030′ are formed on the frontside and backside of the product structure 3002, respectively. By way of example only, a process such as CVD, ALD or PVD can be employed to deposit a suitable etch-stop material (see above) onto the product structure 3002. Following deposition, a process such as CMP can be used to polish the etch-stop material stopping on, and exposing the vias 3006. It is notable that, while not shown in the figure, the structure may be flipped to enable top-down processing when needed. As described above, the alignment marks 3060 and 3060′ can be present on the (frontside/backside) surfaces of the product structure 3002 outward from the vias 3006.

In step 4102, the (front/back) sacrificial test structures 3020 and 3020′ are formed on the frontside and backside respectively of the product structure 3002 over the etch-stop layers 3030 and 3030′ and alignment marks 3060 and 3060′. By way of example only, standard metallization techniques can be employed to form the sacrificial test structures 3020 and 3020′ on the product structure 3002. As described in detail above, the sacrificial test structures 3020/3020′ have the (second) population 3024 of (second) vias 3026/(third) population 3024′ of (third) vias 3026′, each of which can be formed from a contact metal(s) thereby enabling direct metal-to-metal contact between the vias 3006 and the vias 3026/3026′.

As highlighted above, the etch-stop layers 3030 and 3030′ are formed from a different material than the sacrificial test structures 3020 and 3020′ at the interfaces 3028 and 3028′ (see FIG. 3A, above) between the vias 3006 and the vias 3026/3026′ to provide etch selectivity. Further, another unique feature of the present configuration is that the top surface 3032/bottom surface 3032′ (see FIG. 3A, above) of the etch-stop layers 3030/3030′ are coplanar with the interfaces 3028/3028′.

In step 4104, the product structure 3002 is tested through the sacrificial test structure 3020 using the vias 3026 and/or through the sacrificial test structure 3020′ using the vias 3026′. For instance, as shown in FIG. 4B, a test probe 4120 can be used to gain access to the product structure 3002 by way of the vias 3026 which are bonded directly to the vias 3006 and/or by way of the vias 3026′ which are also bonded directly to the vias 3006, rather than directly probing the vias 3006 of the product structure 3002. Doing so, advantageously limits any metal damage 4122 from the testing performed in step 4104 to the sacrificial test structure 3020 which, as its name implies, will be removed later on in the process.

Namely, in step 4106, the sacrificial test structures 3020 and 3020′ are removed along with any metal damage 4122 to it caused by the testing. As described in detail above, an etching process (or combination of etching processes) can be employed in step 4106, stopping on the etch-stop layers 3030/3030′. Suitable etching processes include, but are not limited to, dry etching processes such as RIE, wet chemical etching, and/or CMP. As above, embodiments are contemplated herein where at least a portion of one or more of the etch-stop layers 3030/3030′ remains following the removal etch. However, even in a case where the etch-stop layers 3030/3030′ are completely removed, use of the sacrificial test structures 3020 and 3020′ is still evident by the recesses 3066/recesses 3066′ as depicted, e.g., in FIG. 3E and shadows 3090/3090′ of the alignment marks 3060/3060′.

The now-tested product structure 3002 can then be packaged. However, any further processing that is needed prior to packaging may be performed. For instance, by way of example only, as shown in step 4108, scribing can be used to obtain the desired final product structure 3002 for packaging. Advantageously, any damage resulting from the above-described testing is removed along with the sacrificial test structures 3020 and 3020′. What remains is a clean post-testing interface for packaging, which is especially important for integration techniques such as bumpless bonding. For example, as shown in step 4110 the final product structure 3002 can be joined with complementary product structures 3102/3102′, e.g., by way of bumpless bonding between vias 3006 and 3106″/3106′. In this non-limiting example, the product structures 3102/3102′ are also produced and pre-package tested using the present techniques. As such, the product structures 3102/3102′ include a population 3104″/3104′ of vias 3106″/3106′, an etch-stop layer 3130″/3130′, etc.

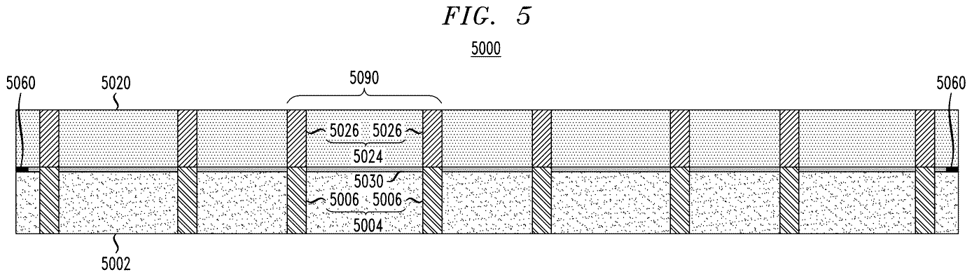

As highlighted above, the present techniques can also be employed at a wafer-level scale. See, for example, FIG. 5 which illustrates a device 5000 that includes a product structure 5002 (in this case a product wafer) having a (first) population 5004 of (first) vias 5006, and a sacrificial test structure 5020 having a (second) population 5024 of (second) vias 5026 disposed on a frontside of the product structure 5002, with an etch-stop layer 5030 therebetween.

While not explicitly shown in the figures, it would be understood by one skilled in the art that the product structure 5002 can have pre-built structures such as transistors, diodes, capacitors, resistors, interconnects, wiring, etc. for specific memory, radio-frequency, logic, etc. applications. As above, the vias 5006 and 5026 can each be formed from a contact metal (e.g., Cu, W, Ni, Pt, Co, Ru, Ti, Ta and/or Al). Alignment marks 5060 can be etched on the surface of the product structure 5002. Post testing, these alignment marks 5060 will help ensure proper positioning of the product structure 5002 with other corresponding structures during packaging.

The use of the sacrificial test structure 5020 advantageously enables testing of the product structure 5002 without incurring metal damage to the product structure 5002 itself. Namely, as described above, any damage will be removed along with the sacrificial test structure 5020 prior to packaging the product structure 5002. Further, in the same manner as described above, any pre-package processing may be carried out such as scribing and separating the product structure 5002 into individual chips 5090.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, such as chemical oxide removal (COR) etching, and reactive ion etching, respectively, which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary device (e.g., device 1000, device 2000, device 3000, device 5000, etc.) includes: a product structure (e.g., product structure 1002, product structure 2002, product structure 3002, product structure 5002, etc.) having vias (e.g., vias 1006, vias 2006, vias 3006, vias 5006, etc.); and an etch-stop layer (e.g., etch-stop layer 1030, etch-stop layer 2030, etch-stop layer 3030, etch-stop layer 5030, etc.) disposed on the product structure in between the vias, such that a surface of the etch-stop layer is coplanar with surfaces of the vias.

The product structure can be, for example, a chip or a wafer. In some non-limiting exemplary cases, the etch stop layer surrounds the vias and there is at least one region of the etch-stop layer that is continuous between the vias. See FIG. 1C, for example, wherein the etch stop layer surrounds the vias 1006 and there is continuous etch stop between the vias along line A-A′ (although metal interconnects 1064 can be present in other locations). In some cases, the etch-stop layer covers the entire area between the two vias, and is adjacent to and surrounding the vias. Features can be combined as appropriate or desired; for example, the product structure can be a chip or a wafer, there can be alignment marks on a surface of the product structure outward from the vias, the etch stop layer can surround the vias, and there can be at least one region of the etch-stop layer that is continuous between the vias.

In accordance with other aspects of the present techniques, another device (e.g., device 1000, device 2000, device 3000, device 5000, etc.) includes: a product structure (e.g., product structure 1002, product structure 2002, product structure 3002, etc.) having vias (e.g., vias 1006, vias 2006, vias 3006, etc.) with recesses (e.g., recesses 1066, recesses 2066, recesses 3066/3066′, etc.) therein; and alignment mark shadows (e.g., shadows 1090, shadows 2090, shadows 3090/3090′, etc.) on at least one (top and/or bottom) surface of the product structure outward from the vias. This product structure can also be, for example, a chip or a wafer.

As seen, for example, in FIGS. 1D and 2D respectively, in some instances, the alignment mark shadows are present on a top surface or a bottom surface of the product structure. In such cases, for example, the recesses are correspondingly present in either an end of the vias corresponding to the top surface of the product structure or an end of the vias corresponding to the bottom surface of the product structure.

Referring to FIG. 3E, for example, in some instances, the alignment mark shadows are present on both a top surface and a bottom surface of the product structure. In such cases, for example, the recesses are present in both an end of the vias corresponding to the top surface of the product structure and an end of the vias corresponding to the bottom surface of the product structure.

In accordance with further aspects of the present techniques, a method includes: forming an etch-stop layer (e.g., etch-stop layer 1030, etch-stop layer 2030, etch-stop layer 3030, etch-stop layer 5030, etc.) on a product structure (e.g., product structure 1002, product structure 2002, product structure 3002, product structure 5002, etc.), where the product structure has first vias (e.g., vias 1006, vias 2006, vias 3006, vias 5006, etc.), and where a top surface of the etch-stop layer is coplanar with top surfaces of the first vias; forming a sacrificial test structure (e.g., sacrificial test structure 1020, sacrificial test structure 2020, sacrificial test structure 3020, sacrificial test structure 5020, etc.) over the etch-stop layer, where the sacrificial test structure has second vias (e.g., vias 1026, vias 2026, vias 3026, vias 5026, etc.) in direct contact with the first vias; testing the product structure through the sacrificial test structure using the second vias; and removing the sacrificial test structure along with any damage to it caused by the testing.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed test-ready product structures.

An integrated circuit in accordance with aspects of the present inventions can be employed in essentially any application and/or electronic system where one or more aspects of the disclosed test-ready product structures would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A device, comprising:
a product structure having vias; and
an etch-stop layer disposed on the product structure in between the vias, such that a surface of the etch-stop layer is coplanar with surfaces of the vias.

2. The device of claim 1, wherein the product structure comprises a chip or a wafer.

3. The device of claim 1, further comprising:
alignment marks on a surface of the product structure outward from the vias.

4. The device of claim 1, wherein the etch stop layer surrounds the vias and there is at least one region of the etch-stop layer that is continuous between the vias.

5. The device of claim 1, wherein the etch-stop layer is disposed on a frontside of the product structure, and wherein a top surface of the etch-stop layer is coplanar with top surfaces of the vias.

6. The device of claim 1, wherein the etch-stop layer is disposed on a backside of the product structure, and wherein a bottom surface of the etch-stop layer is coplanar with bottom surfaces of the vias.

7. The device of claim 1, wherein the etch-stop layer comprises a front etch-stop layer disposed on a frontside of the product structure, and wherein the device further comprises:
a back etch-stop layer disposed on a backside of the product structure.

8. A device, comprising:
a product structure having vias with recesses therein; and
alignment mark shadows on at least one surface of the product structure outward from the vias;
wherein the product structure comprises a chip or a wafer.

9. The device of claim 8, wherein the alignment mark shadows are present on a top surface or a bottom surface of the product structure.

10. The device of claim 9, wherein the recesses are correspondingly present in either an end of the vias corresponding to the top surface of the product structure or an end of the vias corresponding to the bottom surface of the product structure.

11. The device of claim 8, wherein the alignment mark shadows are present on both a top surface and a bottom surface of the product structure.

12. The device of claim 11, wherein the recesses are present in both an end of the vias corresponding to the top surface of the product structure and an end of the vias corresponding to the bottom surface of the product structure.

13. A method, comprising:
forming an etch-stop layer on a product structure, wherein the product structure has first vias, and wherein a top surface of the etch-stop layer is coplanar with top surfaces of the first vias;
forming a sacrificial test structure on the product structure over the etch-stop layer, wherein the sacrificial test structure has second vias in direct contact with the first vias;
testing the product structure through the sacrificial test structure using the second vias; and
removing the sacrificial test structure along with any damage to it caused by the testing.

14. The method of claim 13, wherein the product structure comprises a chip or a wafer.

15. The method of claim 13, wherein the first vias extend fully through the product structure and the second vias extend fully through the sacrificial test structure.

16. The method of claim 13, wherein the first vias and the second vias each comprise at least one contact metal.

17. The method of claim 13, wherein the sacrificial test structure comprises an interlayer dielectric abutting the etch-stop layer, and wherein the etch-stop layer comprises a material having etch selectivity to the interlayer dielectric.

18. The method of claim 13, wherein the sacrificial test structure having the second vias comprises a front sacrificial test structure disposed on a frontside of the product structure, and wherein the method further comprises:
forming another etch-stop layer on a backside of the product structure, wherein a bottom surface of the other etch-stop layer is coplanar with bottom surfaces of the first vias;
forming a back sacrificial test structure having third vias on a backside of the product structure over the other etch-stop layer, wherein the back sacrificial test structure has third vias in direct contact with the first vias; and
testing the product structure through the front sacrificial test structure using the second vias and through the back sacrificial test structure using the third vias.

19. The method of claim 13, wherein at least a portion of the etch-stop layer remains on the product structure following the removing of the sacrificial test structure.

20. The method of claim 13, further comprising:
joining the product structure, after removal of the sacrificial test structure, with another product structure using bumpless bonding.
